(19) United States
(12) Patent Application Publication
(10) Pub. No.: US 2008/0139007 A1
(43) Pub. Date: Jun. 12, 2008

(54) Electrical connector

(75) Inventor: Takashi Nagawatari, Tokyo (JP)

Correspondence Address: TAKUCHI & KUBOTERA, LLP, 200 Daingerfield Road, Suite 202, Alexandria, VA, 22314, US

(73) Assignee: Hirose Electric Co., Ltd.

(21) Appl. No.: 11/984,269

(22) Filed: Nov. 15, 2007

(30) Foreign Application Priority Data
Dec. 7, 2006 (JP) 2006-330059

(51) Int. Cl. H01R 12/14

(52) U.S. Cl. 439/55

(57) ABSTRACT

A female terminal structure connector and a male terminal structure connector constitute an electrical connector. The electrical connector includes a plurality of terminals made of a metal sheet and arranged in a housing in a plate thickness direction thereof to face with each other in plate surfaces. The terminals are fitted into each other on a fitting surface provided on the housing. In the electrical connector, the terminal extends in a direction perpendicular to a fitting surface. A part of the terminal situated on a fitting surface side has a contact portion in a plate surface parallel to a fitting direction thereof. Further, the terminal of at least one of the connectors has an elastic portion to elastically bend in a plate thickness direction in a part of the terminal. The contact portion is provided in the elastic portion.

The present invention relates to an electrical connector to fit to each other.

An electrical connector is provided with a plurality of terminals maintaining a flat plate surface of a metal sheet and arranged in a housing in a plate thickness direction thereof. For example, the connector in Patent Reference has been known.

In Patent Reference, a pair of connectors to fit into each other has the flat terminals described above. An outer dimension of such a terminal in an arrangement direction thereof is equal to a plate thickness dimension; and therefore, the terminal is thin. Accordingly, a plurality of such terminals may be arranged in a high density.

The terminal of the both connectors has a plane shape having an S-shape portion. Further, when the connectors are fitted into each other, the terminals are adjacent to an edge surface on a free edge side of the S-shape portion or a surface of a plate thickness width thereof. The S-shape portion is elastic inside of the plane described above because of the shape, and contacts through an elastic contact. An elastic force applied to the terminals through the elastic contact influences on a sidewall of the housing at a right angle. The sidewall of the housing holds the terminals and extends long in an arrangement direction with respect to the terminals. One of two bend portions provided at the S-shape portion fits into the sidewall. The sidewall is not that much made thick.

In Patent Reference, the terminals of the connectors are arranged in two rows to face with each other. Accordingly, the terminals generate a symmetrical elastic pressure force. Further, the elastic pressure force is applied in a direction to divide the sidewalls of the housing.

### Patent Reference; Japanese Patent Publication No. 2004-241253

In the connector of Patent Reference 1, the terminals are made to be in the S-shape to maintain the plane of the metal sheet. Edge surfaces of the S-shape portion elastically contact with each other, which causes some flaws.

First, a dimension of the terminal in an arrangement direction thereof is a plate thickness. That is, the terminal is made thin. Since a large number of the terminals are arranged, the sidewall of the housing becomes long. The sidewall of the housing is made relatively thin and forces applied from all the terminals to the sidewall are combined to be large because of the number of the terminals. Accordingly, the sidewall tends to be bent outwardly. An amount of bending is the largest in a center position in the arrangement direction thereof. Accordingly, a contact pressure with a mating connector may vary depending on a position in the arrangement direction with respect to the terminal. Consequently, a strength of the terminal on the sidewall or a variance of the contact pressure among the terminals may be an issue.

Further, the terminal is contacted to the mating connector within a plate thickness. Accordingly, when there is a variation made at a production or there is a displacement upon fitting in a position of the terminal in an arrangement direction or in a plate thickness direction thereof, the terminal and the mating terminal contact each other in a small surface. The reduction in the contact area is not preferred because an electric resistance is increased and a signal is deteriorated. The displacement may occur when the terminal fits into the mating connector in a twisted state. Further, when the displacement is great, the terminal may be possibly short-circuited with an adjacent terminal through the mating terminal.

Further, the terminal is enlarged in a fitting direction with respect to the connector to maintain enough elasticity in the S-shape portion thereof. Accordingly, the connector may be enlarged in the direction. This type of the connector is often arranged on a substrate to connect the substrates. Accordingly, the connector is preferred to be small and a low profile, which may not be satisfied by the conventional connector.

The present invention is made in consideration of the problem described above. An object of the present invention is to provide a low profile electrical connector capable of preventing an overload to a sidewall of a housing and obtaining a stable contact.

Further objects and advantages of the invention will be apparent from the following description of the invention.

### SUMMARY OF THE INVENTION

In order to attain the objects described above, according to an embodiment of the present invention, an electrical connector includes a plurality of terminals made of a metal sheet and arranged in a housing in a plate thickness direction thereof to face with each other in plate surfaces. Further, the terminals are fitted into each other on a fitting surface provided on the housing. A female terminal structure connector and a male terminal structure connector constitute a pair of the electrical connectors.

In the pair of the electrical connectors of the present invention, the terminal of the connectors extends in a direction perpendicular to a fitting surface. A part of the terminal situated on a fitting surface side has a contact portion in a plate surface parallel to a fitting direction thereof. Further, the terminal of at least one of the connectors has an elastic portion to elastically bend in a plate thickness direction in a part of the terminal. The contact portion is provided in the elastic portion.

According to the present invention, when a pair of the connectors fits into each other, the terminals of the connectors become adjacent to each other in a width direction (fitting direction) in a direction parallel to a plate surface of the terminals, and the plate surface thereof contacts each other. At this time, the terminal of at least one of the connectors has an elastic pressure in a plate thickness direction thereof. Accordingly, the contact portions of the terminals of the both connectors elastically contact with the plate surfaces in a plate thickness direction thereof. As a result, even though the contact portions are somewhat displaced from a regular position in a fitting direction with respect to the connector, there is no effect because the plate surfaces of the contact portions are large enough to maintain enough contact area.

The connector according to the present invention has the terminal having a small plate thickness in an arrangement direction with respect to the terminal. Accordingly, the connector is small. Further, a width of the terminal in a fitting direction thereof does not have to be large, and the connector may be small in the direction. A total force of elastic contact forces applied to a plurality of the terminals influences on an edge wall of the housing in an arrangement direction with respect to the terminal. Accordingly, little deformation of the edge wall that is relatively short occurs. Therefore, the sidewall that is long in an arrangement direction with respect to the terminal has no influence from the terminal, and the sidewall may not be bent. Accordingly, there are no fluctuations in the contact pressure among a plurality of the terminals.

In the present invention, a pair of the connectors comprises the male terminal structure connector and the female terminal structure connector. The male terminal structure connector has the contact portion protruding from a fitting surface of the housing. The female terminal structure connector is situated inside of the receiving recess portion. The receiving recess portion is recessed from the fitting portion. The connectors may be formed so that the contact portion of the male terminal structure connector may enter the receiving recess portion.

In the receiving recess portion, the contact portion of the terminal of the male terminal structure connector may be accommodated. The contact portion of the terminal of the male terminal structure connector may be designed to contact an inner wall surface of the receiving recess portion to be supported without a bend of a plate surface or to contact an inner wall surface of the receiving recess portion to be supported when the plate surface receives an elastic pressure from the mating female terminal structure connector to bend no more than a defined amount. Further, the plate surface may be bent or provided with a space with the inner wall surface. In any case, the contact portions of the terminal of the connectors contact each other to bend within the receiving recess portion. Accordingly, the terminal does not contact an adjacent terminal no matter how much the contact portion is bent.

In the present invention, the terminal of the female terminal structure connector has an elastic portion. The elastic portion is the contact portion on the free edge of the terminal that keeps a specific distance from the inner wall surface of the receiving recess portion. Accordingly, the elastic portion that is the contact portion of the terminal of the female terminal structure connector is bent inside of the receiving recess portion. Further, a position of the contact portion of the terminal of the male terminal structure connector may be regulated in a plate thickness direction thereof inside of the inner wall surface of the receiving recess portion.

Further, the terminal of the male terminal structure connector may be made so that the contact portion is an elastic portion on an edge portion.

In the present invention, when the male terminal structure connector is situated inside of the corresponding opening portion, the connection portion that is connected to a circuit surface of the substrate is provided on an edge of the terminal. Further, the connection portion may protrude from the opening portion and engage with the circuit surface. Accordingly, the approximate entire connector may be accommodated inside of the opening portion of the substrate and only the connection portion of the terminal may be exposed on a circuit surface of the substrate. Therefore, the connector may be produced to have a low profile. In this case, the connection portion of the male terminal structure connector engages with the circuit surface of the substrate situated on a receiving side of the female terminal structure connector.

In the present invention, the connection portion of one of the male terminal structure connector and the female terminal structure connector may be exposed from a bottom surface of the housing on an opposite side of the receiving side of each other. Accordingly, the connector may be placed on the circuit surface of the substrate or a flat cable and connected with the circuit surface with solder or the like.

In the present invention, the male terminal structure connector may be covered with a shield plate on an opposite side of the receiving side for the female terminal structure connector. Accordingly, the male terminal structure connector may obtain a shield effect when the male terminal structure connector is accommodated inside of the corresponding opening portion. When the female terminal structure connector is accommodated inside of the male terminal structure connector, the shield plate covers the female terminal structure connector. Accordingly, the both connectors obtain the shield effect. A portion of the shield plate may be supported on the substrate surface. Further, the shield plate may be accommodated within the substrate thickness.

In the present invention, as described above, the terminal made of a metal sheet is provided to extend in a direction perpendicular to the fitting surface with respect to the housing. Further, when the connectors fit into each other, the terminals contact with each other in the contact portions provided on the plate surfaces in a plate thickness direction thereof. Accordingly, no force is applied to the sidewall of the housing from the terminal upon fitting the connectors. The sidewall of the housing extends long in an arrangement direction with respect to the terminals.

Further, a deformation of the sidewall of the housing or a fluctuation of the contact pressure in the terminals does not occur. In addition, the contact portion provided in the plate surface has a relatively large area. Accordingly, the terminals have an enough contact area and may transmit a stable signal regardless of a little positional displacement of the terminals. Further, the size of the terminal may be kept small in a fitting direction thereof; therefore, the connector may have a low profile in the direction.

### BRIEF DESCRIPTION OF THE DRAWINGS

FIGS. 1(A) and 1(B) are plan views showing a pair of electrical connectors according to an embodiment of the present invention, wherein FIG. 1(A) is a plan view showing a female terminal structure connector and FIG. 1(B) is a plan view showing a male terminal structure connector;

FIGS. 2(A) and 2(B) are sectional views showing the pair of electrical connectors according to the embodiment of the present invention, wherein FIG. 2(A) is a sectional view showing a state before the electrical connectors are fitted and FIG. 2(B) is a sectional view showing a state after the electrical connectors are fitted;

FIGS. 3(A) and 3(B) are enlarged views showing the pair of electrical connectors according to the embodiment of the present invention, wherein FIG. 3(A) is an enlarged view showing the female terminal structure connector and FIG. 3(B) is an enlarged view showing the male terminal structure connector;

FIG. 4 is a plan view showing the pair of electrical connectors in a fitted state according to the embodiment of the present invention;

FIGS. 5(A) to 5(D) are sectional views showing terminals of the electrical connectors according to the embodiment of the present invention, wherein FIG. 5(A) is a sectional view showing a state before the electrical connectors are fitted, FIG. 5(B) is a sectional view showing a state that the electrical connectors start being fitted, FIG. 5(C) is a sectional view showing a state during the electrical connectors are fitted, and FIG. 5(D) is a sectional view showing a state after the electrical connectors are fitted;

FIGS. 6(A) and 6(B) are enlarged plan views showing an essential portion of the pair of electrical connectors according to the embodiment of the present invention, wherein FIG. 6(A) is a plan view showing a state before the electrical connectors are fitted and FIG. 6(B) is a plan view showing a state after the electrical connectors are fitted;

FIG. 7 is a sectional view showing a pair of electrical connectors in a state before the electrical connectors are fitted according to another embodiment of the present invention; and

FIG. 8 is a sectional view showing a pair of electrical connectors in a state after the electrical connectors are fitted according to a further embodiment of the present invention.

### DETAILED DESCRIPTION OF THE PREFERRED EMBODIMENTS

Hereunder, embodiments of the present invention will be explained with reference to the accompanying drawings.

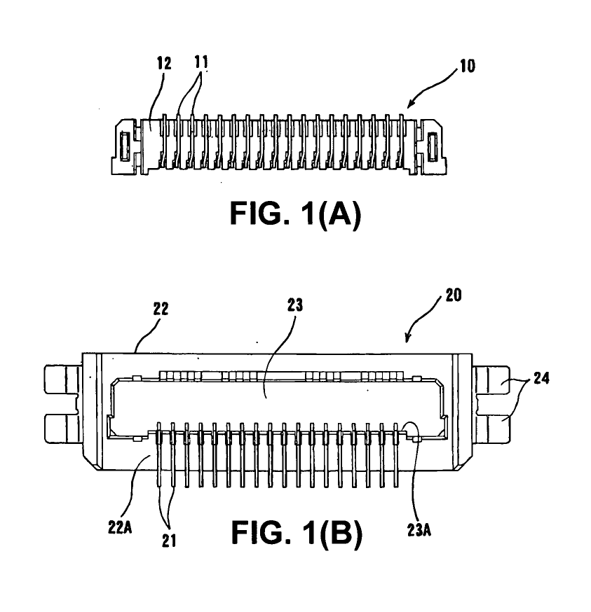

FIGS. 1(A) and 1(B) are plan views showing a pair of electrical connectors according to an embodiment of the present invention. FIG. 1(A) is a plan view showing a female terminal structure connector 10 and FIG. 1(B) is a plan view showing a male terminal structure connector 20.

As shown in FIG. 1(A), the female terminal structure connector 10 is provided with a plurality of terminals 11. A plurality of the terminals 11 having a plate shape and made of a metal sheet is arranged on a housing 12 in a plate thickness direction or a direction perpendicular to a plate surface thereof. The male terminal structure connector 20 is provided with a receiving recess portion 23 to receive the female terminal structure connector 10.

As shown in FIG. 1(B), the receiving recess portion 23 is provided in a housing 22 to pass through as a window. Further, a plurality of terminals 21 having a plate shape is arranged along one of sidewalls 22A provided in the housing 22 in a plate thickness direction or a direction perpendicular to a plate surface thereof. An inner wall surface of the receiving recess portion 23 constitutes a fitting surface 23A having an appropriate shape and size to fit to the female terminal structure connector 10. The male terminal structure connector 20 is provided with clamps 34 to attach the male terminal structure connector 20 to a substrate (not shown). The clamps 34 extend outside of the housing 22 from both ends thereof in an arrangement direction of the terminals.

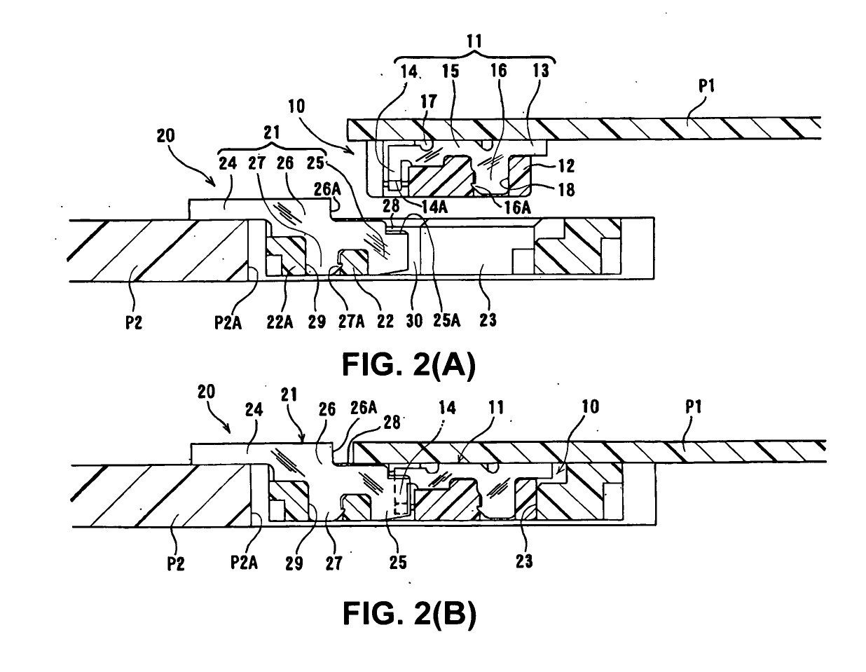

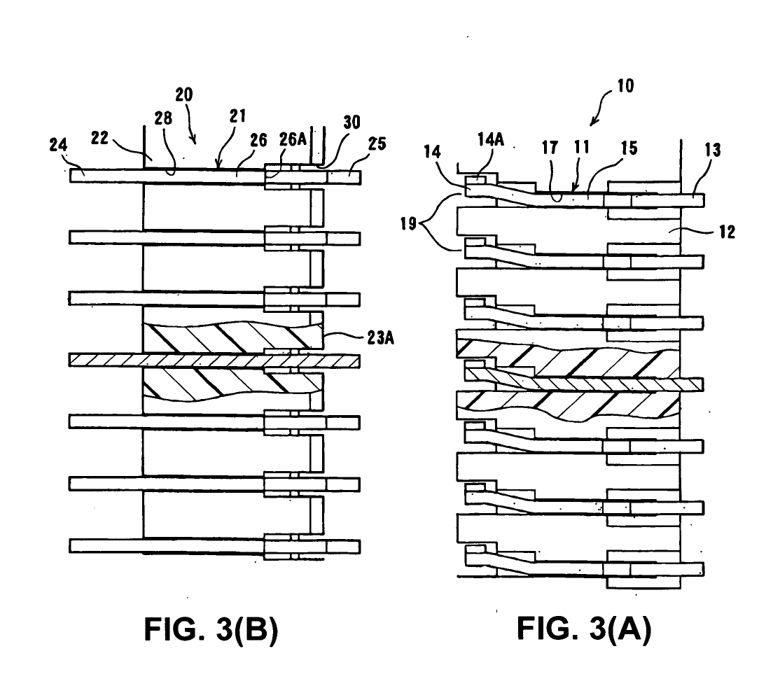

FIGS. 2(A) and 2(B) are sectional views showing the pair of electrical connectors according to the embodiment of the present invention. FIG. 2(A) is a sectional view showing a state before the electrical connectors are fitted, and FIG. 2(B) is a sectional view showing a state after the electrical connectors are fitted. FIGS. 3(A) and 3(B) are enlarged views showing the pair of electrical connectors according to the embodiment of the present invention. FIG. 3(A) is an enlarged view showing the female terminal structure connector 10, and FIG. 3(B) is an enlarged view showing the male terminal structure connector 20.

As shown in FIG. 2(A), the terminals 11 having a flat plate surface parallel to a sheet surface are arranged on the housing 12 in the female terminal structure connector 10. Further, the terminals 11 are arranged at a specific pitch in a perpendicular direction with respect to the sheet surface. The terminal 11 comprises a connection portion 13, a contact portion 14, a joining portion 15, and a fixed portion 16. The connection portion 13 connects the terminal 11 and a flexible circuit board P1 or a circuit portion of the substrate with solder. The contact portion 14 is provided to contact with the terminals 21 of the male terminal structure connector 20. The joining portion 15 connects the connection portion 13 and the contact portion 14. Further, the fixed portion 16 is provided to fix the terminals 11 to the housing 12.

As shown in FIG. 2(A), the connection portion 13 and the joining portion 15 of the terminal 11 are situated so that top edges of the connection portion 13 and the joining portion 15 slightly protrude upwardly from the housing 12 to contact with the flexible circuit board P1.

As shown in FIG. 3(A), the joining portion 15 has a slight slope in a left portion that is closer to the corresponding terminal 21 of the male terminal structure connector 20. The terminal 11 does not require the slope, and the portion may be a plane.

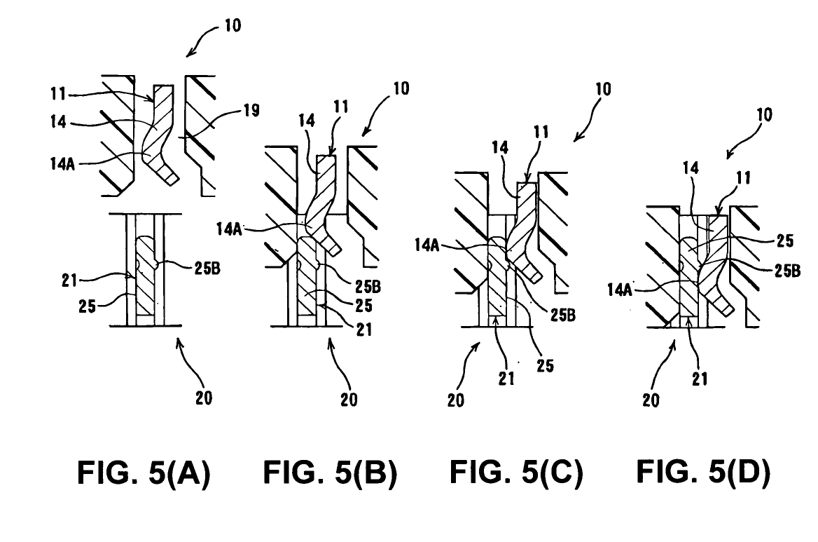

As shown in FIG. 2(A), the contact portion 14 is provided to extend downwardly on a left edge. Further, as shown in FIGS. 5(A) to 5(D), the contact protrusion portion 14A is provided to protrude upwardly in a plate thickness direction thereof to be closer to the corresponding terminal 21 on a lower edge side of the contact portion 14. The connection portion 13 extends to a right side in FIG. 2(A) to be situated outside of the housing 12. The fixed portion 16 extends downwardly from a border of the joining portion 15 and the connection portion 13. Further, the protrusion 16A having a nail-like shape is provided on a side edge of the fixed portion 16 for fixing.

In the embodiment, the housing 12 of the female terminal structure connector 10 is provided with a receiving groove 17 and a fixed groove 18 as shown in FIG. 2(A). The receiving groove 17 is provided to open upwardly, and the joining portion 15 and the connection portion 13 fit into the receiving groove 17 from above. The fixed groove 18 is provided to pass through downwardly. Further, the fixed portion 16 communicates with the receiving groove 17 and is pressed into the fixed groove 18.

In the embodiment, the housing 12 has a receiving recess portion 19 having a space in a plate thickness direction with respect to the contact portion 14 of the terminal 11 as shown in FIG. 3(A). The receiving recess portion 19 allows the contact portion of the terminal 21 of the male terminal structure connector 20 to enter while communicating with a space formed with respect to a slope portion on a left edge of the joining portion 15. When the terminal 21 of the male terminal structure connector 20 enters to contact with the contact portion, a deformation is allowed only in a range covering from the slope portion to the contact portion 14.

In the embodiment, the female terminal structure connector 10 is attached to the flexible circuit board P1, and the connection portion 13 is connected to the corresponding circuit portion with solder.

The male terminal structure connector 20 fits into the female terminal structure connector 10. Similar to the female terminal structure connector 10, a plurality of the terminals 21 having a plate shape and made of a sheet plate is arranged in the housing 22 in a plate thickness direction or a direction perpendicular to a plate surface thereof. As shown in FIGS. 1(B) and 2(A), the terminals 21 are provided on the sidewall 22A, one of the surrounding walls of the housing that is provided with the receiving recess portion 23 having the fitting surface 23A for the female terminal structure connector 10.

As shown in FIG. 2(A), the terminal 21 has a flat plate surface parallel to a sheet surface. The terminal 21 comprises a connection portion 24, a contact portion 25, a joining portion 26, and a fixed portion 27. The connection portion 24 is situated on a surface of a corresponding circuit of a circuit board P2 outside of an opening portion P2-A when the opening portion P2-A of the circuit board P2 accommodates the male terminal structure connector 20. The contact portion 25 contacts with the contact portion 14 of the terminal 11 of the female terminal structure connector 10. The joining portion 26 connects the contact portion 25 and the connection portion 24. Further, the fixed portion 27 is provided to fix the terminal 21 to the housing 22.

As shown in FIG. 2(A), the joining portion 26 has a step portion 26A on an upper edge in a position corresponding with the fixed portion 27 in a vertical direction thereof. A left side of the step 26A is flush with an upper edge of the connection portion 24. Further, a right side of the step portion 26A is buried to be flush with an upper face of the circuit board P2 so that an edge of the flexible circuit board P1 connected to the female terminal structure connector 10 is accommodated.

As shown in FIG. 2(A), the contact portion 25 extends downwardly in a leg shape. A top edge of the contact portion 25 is formed to be a taper edge 25A to support an engagement with the contact portion 14 of the terminal 11 of the female terminal structure connector 10. The contact portion 25 includes an engagement protrusion portion 25B to engage with the contact portion 14 at a specific fitting position (shown in FIGS. 5(A) to 5(D)). Further, the fixed portion 27 extends downwardly parallel to the contact portion 25 in a leg shape as shown in FIG. 2(A), and a protrusion 27A having a nail-like shape is provided on a side edge thereof for fixing. The contact portion 25 and the fixed portion 27 extend no more than a thickness of the circuit board P2.

As shown in FIG. 2(A), the housing 22 of the male terminal structure connector 20 includes a receiving groove 28 and a fixed groove 29. The receiving groove 28 is formed to be open upwardly to receive a part of the joining portion 26 and the connection portion 24 from above. The fixed groove 29 is communicated with the receiving groove 28 and provided to pass through downwardly, so that the fixed portion 27 of the terminal 21 is pressed into the fixed groove 29.

In the embodiment, the housing 22 has a recess portion 30 open to the receiving recess portion 23 as shown in FIG. 3(B). The recess portion 30 has a space against the contact portion 25 of the terminal 21 in a thickness direction with respect to the contact portion 25. Accordingly, the contact portion 25 is elastic in the thickness direction thereof and may be elastically deformed inside of the recess portion 30. The recess portion 30 has a depth in a horizontal direction thereof in FIG. 2(A), so that a right portion of the contact portion 25 protrudes from the recess portion 30.

In the embodiment, the male terminal structure connector 20 is accommodated in the opening portion P2A of the circuit board P2. In the male terminal structure connector 20 accommodated in the opening portion P2A, the connection portion 24 of the terminal 21 is situated outside of the opening portion P2A of the circuit board P2 in a thickness direction of the circuit board, and a lower edge of the connection portion 24 is situated on a corresponding circuit portion of the circuit board P2. The connection portion 24 is connected with the corresponding circuit portion with solder.

In the embodiment, the female terminal structure connector 10 and the male terminal structure connector 20 described above are connected as described below.

As shown in FIG. 2(A), the female terminal structure connector 10 is situated above the male terminal structure connector 20. The female terminal structure connector 10 is attached and connected to the flexible circuit board P1, and the male terminal structure connector 20 is accommodated to the opening portion P2A of the circuit board P2 to be connected to the circuit board P2. Plan views of the female terminal structure connector 10 and the male terminal structure connector 20 when the flexible circuit board P1 and the circuit board P2 are omitted are shown in FIGS. 3(A) and 3(B), respectively.

Next, as shown in FIG. 2(B), the female terminal structure connector 10 is pulled down and accommodated in the receiving recess portion 23 of the male terminal structure connector 20. The contact portion 25, i.e., a distal side of the terminal 21 of the male terminal structure connector 20, protrudes from the fitting surface 23A of the receiving recess portion 23 as shown in FIG. 3(B).

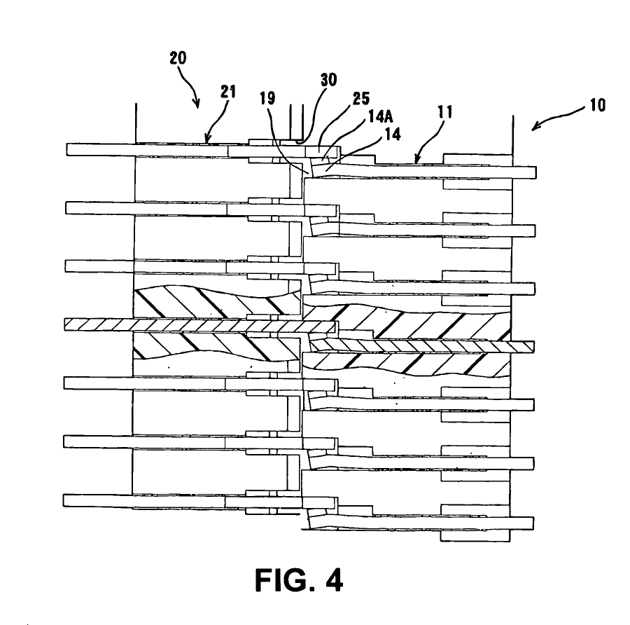

As shown in FIGS. 5(A) to 5(D), the contact portion 25 enters the receiving recess portion 19 of the female terminal structure connector 10. At this time, the contact portion 25 of the male terminal structure connector 20 is guided along or is adjacent to one of the inner wall surfaces of the receiving recess portion 19 situated on a contact protrusion portion 14A side of the contact portion 14 of the female terminal structure connector 10. Further, the contact portion 25 of the male terminal structure connector 20 enters between the inner wall surface and the contact protrusion portion 14A to press the contact portion 14 in the contact protrusion portion 14A, thereby generating an elastic flexure in a plate thickness direction of the contact portion 14. Accordingly, a contact pressure is generated between the contact portions 25 and 14 as shown in FIGS. 4 and 5(A) to 5(D).

When the female terminal structure connector 10 and the male terminal structure connector 20 fit to a specific depth, the contact protrusion portion 14A of the terminal 11 of the female terminal structure connector 10 engages with the engagement protrusion portion 25B of the terminal 21 of the male terminal structure connector 20 as shown in FIG. 5(D). Accordingly, a fitting of the connectors to a specific fitting position may be confirmed with a click, and a separation of the connectors may be prevented.

In the embodiment, the terminals 11 and 21 of the connectors 10 and 20 have the contact pressure at the contact portions 14 and 25 in a plate thickness direction of the terminals. At this time, the contact portion 25 of the male terminal structure connector 20 is supported in or is adjacent to one of the inner wall surfaces of the receiving recess portion 19 of the female terminal structure connector 10. The contact portion 14 of the female terminal structure connector 10 is elastically deformed and is supported in or is adjacent to the other inner wall surface of the receiving recess portion 19 as shown in FIG. 4.

Accordingly, the terminals 11 and 21 of the female terminal structure connector 10 and the male terminal structure connector 20 are connected through the contact pressure. At this time, the contact portion 25 of the terminal 21 of the male terminal structure connector 20 has a space with the inner wall surface of the recess portion 30 inside the recess portion 30 of the male terminal structure connector 20, and may be elastically bent. Accordingly, the terminals is provided with a floating effect (following deformation).

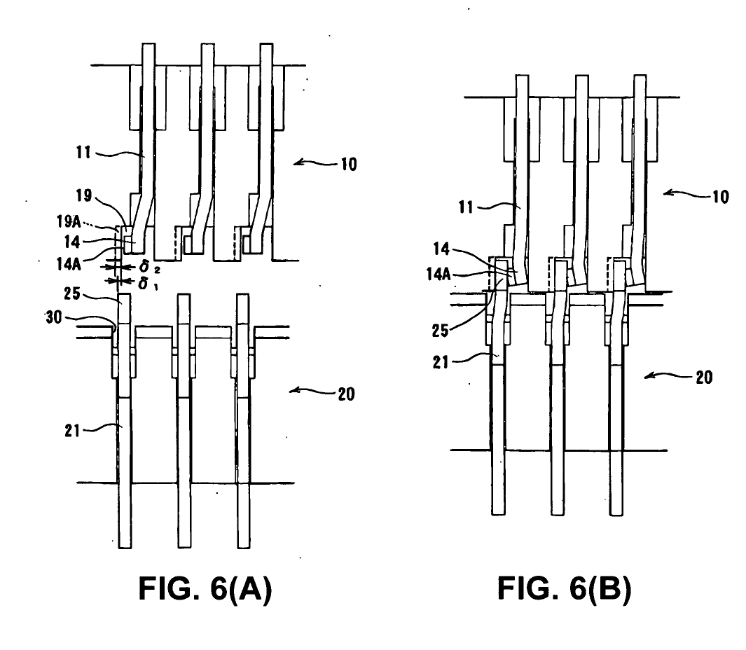

FIGS. 6(A) and 6(B) are enlarged plan views showing an essential portion of the pair of electrical connectors according to the embodiment of the present invention. FIG. 6(A) is a plan view showing a state before the electrical connectors are fitted, and FIG. 6(B) is a plan view showing a state after the electrical connectors are fitted.

As shown in FIG. 6(A), a taper portion 19A having a width of δ₂ larger than δ₁ is provided on a lower surface or a fitting side of the receiving recess portion 19 of the female terminal structure connector 10. Accordingly, when the contact portion 25 of the terminal 21 of the male terminal structure connector 20 is displaced to a position in which the contact portion 25 interferes for δ₁ against the inner wall surface of the receiving recess portion 19 provided in the housing of female terminal structure connector 10, the contact portion 25 of the male terminal structure connector 20 is led by the taper portion 19A of the female terminal structure connector 10 to enter the receiving recess portion 19 and contacts with the contact portion 14 of the terminal 11 of the female terminal structure connector 10 as shown in FIG. 6(B). Accordingly, the contact portion 25 of the male terminal structure connector 20 can be elastically bent to obtain the floating effect within the range of δ₂.

The present invention is not limited to the embodiments shown in FIGS. 1(A)-1(B) to 6(A)-6(B). Various changes may be made to the present invention. For example, the male terminal structure connector may not be accommodated to the opening portion of the substrate. Instead, the male terminal structure connector may be arranged on and connected to the substrate.

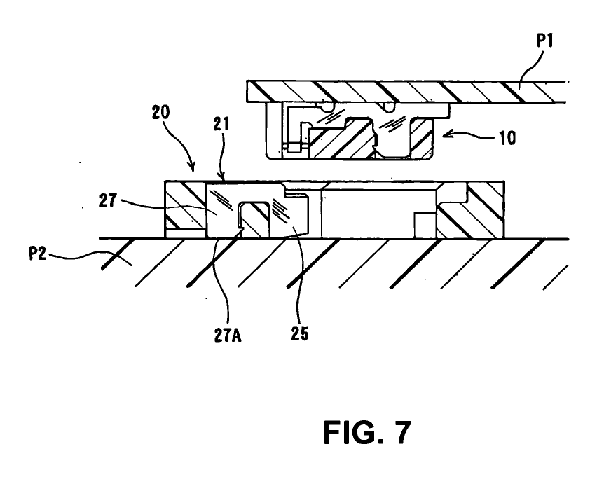

FIG. 7 is a sectional view showing a pair of electrical connectors in a state before the electrical connectors are fitted according to another embodiment of the present invention. As shown in FIG. 7, the terminal 21 of the male terminal structure connector 20 extends so that a lower edge of the fixed portion 27 is adjacent to a surface of the circuit board P2. Accordingly, the lower edge forms a connection portion 37A.

In the embodiment shown in FIG. 7, the connection portion does not protrude from the housing as the embodiment shown in FIGS. 2(A) and 2(B). The connection portion 37A is connected to a corresponding circuit portion of the circuit board P2 with solder.

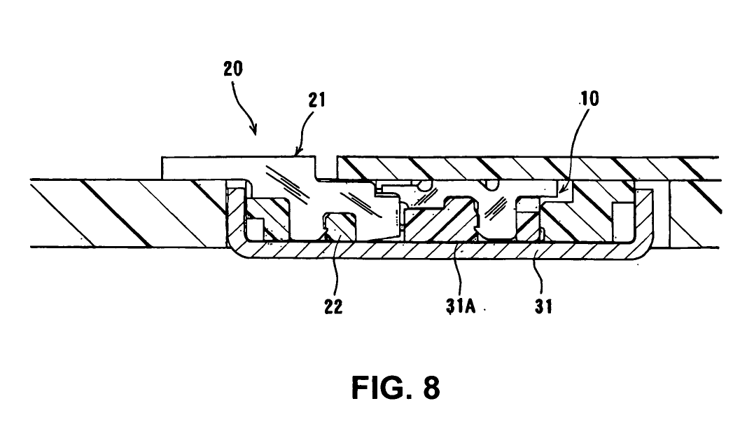

FIG. 8 is a sectional view showing electrical connectors in a state after the electrical connectors are fitted according to a further embodiment of the present invention. In the embodiment shown in FIG. 8, the male terminal structure connector 20 has a shield plate 31. The shield plate 31 having a U-shape section covers the male terminal structure connector 20 from below. An inner surface of the shield 31 is provided with an insulative layer 31A to prevent a short circuit of the terminal 21 and the shield plate 31.

The shield plate 31 may be attached to the housing 22. Further, a flange portion (not shown) extending from a top edge of the sidewall in a perpendicular direction with respect to a sheet surface may engage with a top edge of the opening portion of the substrate.

The disclosure of Japanese Patent Application No. 2006-330059, filed on Dec. 7, 2006 is incorporated in the application by reference.

While the invention has been explained with reference to the specific embodiments of the invention, the explanation is illustrative and the invention is limited only by the appended claims.

What is claimed is:

1. An electrical connector comprising;
a male connector having a first housing, a first terminal disposed in the first housing, said first terminal including a first contact portion; and
a female connector to be fitted to the male connector and having a second housing, a second terminal disposed in the second housing, said second terminal including a second contact portion, at least one of said first terminal and said second terminal including an elastic portion elastically deformable in a thickness direction of the one of the first terminal and the second terminal.

2. The electrical connector according to claim 1, wherein said first housing includes a first fitting surface contacting with a second fitting surface of the second housing, said first terminal being disposed to protrude from the fitting surface.

3. The electrical connector according to claim 1, wherein said second housing includes a receiving recess portion for receiving the male connector, said second terminal being disposed in the receiving recess portion.

4. The electrical connector according to claim 3, wherein said second terminal includes the elastic portion at a free end portion thereof situated away from an inner wall of the receiving recess.

5. The electrical connector according to claim 1, wherein said first terminal includes the elastic portion at one end portion thereof.

6. The electrical connector according to claim 1, wherein said first terminal includes a connecting portion to be connected to a circuit surface of a circuit board.

7. The electrical connector according to claim 6, wherein said connecting portion is arranged to engage the circuit surface.

8. The electrical connector according to claim 1, wherein at least of said first terminal and said second terminal includes a connecting portion protruding from a bottom surface of one of the first housing and the second housing.

9. The electrical connector according to claim 1, wherein said female connector further includes a shield plate.
